(19) United States
(12) Patent Application Publication
(10) Pub. No.: US 2021/0207272 A1
(43) Pub. Date: Jul. 8, 2021

(54) MAGNESIUM ALLOY LAYERED COMPOSITES FOR ELECTRONIC DEVICES

(71) Applicant: Hewlett-Packard Development Company, L.P., Spring, TX (US)

(72) Inventors: Kuan-Ting Wu, Taipei (TW); Chi Hao Chang, Taipei (TW); Chalam Kashyap, Fort Collins, CO (US)

(73) Assignee: Hewlett-Packard Development Company, L.P., Spring, TX (US)

(21) Appl. No.: 17/046,011

(22) PCT Filed: Sep. 25, 2018
(86) PCT No.: PCT/US2018/052518

§ 371 Date: Oct. 8, 2020

(51) Int. Cl. C23C 28/04; C23C 18/12; C23C 22/07; B05D 7/00; C09D 175/04

(52) U.S. Cl. CPC C23C 28/04; C23C 18/1254; C23C 18/122; H05K 5/04; B05D 7/51; B05D 7/576; C09D 175/04; C23C 22/07

(57) ABSTRACT

A magnesium alloy layered composite for an electronic device can include a magnesium alloy substrate, a passivation layer positioned on the magnesium alloy substrate, and a sol-gel layer positioned on the passivation layer. The passivation layer can include a molybdate, a vanadate, a phosphate, a chromate, a stannate, or a manganese salt. The sol-gel layer can include a silicate, a silane, a siloxane, or a metal C1-C5 alkoxide.

### BACKGROUND

Electronics and other devices often include a substrate, such as a metal substrate, that may act as a housing or support for electronic components. In some cases, that housing includes an outer surface that is visible to the user, and thus, a level of attractiveness can be desirable in many instances. The outer surface may also provide protection from the ambient environment if the outer surface is metal, for example. Thus, coatings for substrates, such as metal substrates, can be useful if they can provide some protection and/or provide an attractive appearance.

### BRIEF DESCRIPTION OF THE DRAWINGS

FIG. 1 is a schematic cross-sectional view of an example magnesium alloy layered composite for an electronic device in accordance with examples of the present disclosure;

FIG. 2 is a schematic cross-sectional view of an alternative example magnesium alloy layered composite for an electronic device with passivation layers and sol-gel layers on both sides of a magnesium metal alloy substrate in accordance with examples of the present disclosure;

FIG. 3 is a schematic cross-sectional view of an alternative example magnesium alloy layered composite for an electronic device with a finish coating of a single clear protection layer in accordance with examples of the present disclosure;

FIG. 4 is a schematic cross-sectional view of an alternative example magnesium alloy layered composite for an electronic device with a finish coating of multiple protection layers in accordance with examples of the present disclosure;

FIG. 5 is a schematic cross-sectional view of an alternative example magnesium alloy layered composite for an electronic device with a finish coating of a single clear protection layer on one side and multiple protection layers on the other side in accordance with examples of the present disclosure; and

FIG. 6 is a flow chart depicting an example method of protecting a magnesium alloy from corrosion in accordance with examples of the present disclosure.

### DETAILED DESCRIPTION

Magnesium alloy substrates can be composited with other layers to provide, in some cases, a composite with multiple protections to ameliorate corrosion. Thus, layers including a passivation layer along with a sol-gel coating layer can be applied to one or both sides of the magnesium alloy substrate, and in some examples, other layer(s) such as finishing layer(s), e.g., a clear resin layer, a colored resin layer with dispersed particulates, or both, can likewise be applied. In aggregate, the finishing layer(s) can be referred to collectively as a “finish coating,” whether there be one finishing layer or multiple finishing layers.

In accordance with this, a magnesium alloy layered composite for an electronic device can include a magnesium alloy substrate, a passivation layer positioned on the magnesium alloy substrate, and a sol-gel layer positioned on the passivation layer. The passivation layer can include a molybdate, a vanadate, a phosphate, a chromate, a stannate, or a manganese salt. The sol-gel layer can include a silicate, a silane, a siloxane, or a metal C1-C5 alkoxide. More specific examples of sol-gel layers include tetraethylorthosilicate, tetramethylorthosilicate, tetraisopropoxysilane, aluminum isopropoxide, titanium isopropoxide, aluminum tert-butoxide, glycidoxypropyltriethoxysilane, 3-aminopropyltriethoxysilane, methacryloxypropyltrimethoxysilane, vinyltrimethylsiloxane, diphenyldimethoxysilane, zirconium isopropoxide, or a combination thereof. The magnesium alloy layered composite can further include a finish coating including a protective resin positioned on the sol-gel layer, e.g., clear protective coating, visible protective coating, both visible protective coating and clear protective coating, etc. For example, the finish coating can include multiple finishing layers, including a visible protection layer with particulates suspended in a resin positioned on the sol-gel coating layer, and a clear protection layer including the same resin or a different resin positioned on the visible protection layer. The particulates can include, for example, carbon black, titanium dioxide, clay, mica, talc, barium sulfate, calcium carbonate, synthetic pigment, metallic powder, aluminum oxide (alumina), zirconia, aluminum silicate, zirconium silicate, alumina-zirconia, chromia, graphene, graphite, or a combination thereof. In examples herein, the finish coating can include one or multiple finishing layers having a total thickness from about 10 μm to about 70 μm. In further detail, the passivation layer can have a thickness from about 0.3 μm to about 5 μm. The sol-gel layer can have a thickness from about 2 μm to about 15 μm.

In another example, an electronic device can include a magnesium alloy layered composite including a magnesium alloy substrate with a first surface and a second surface facing an opposing direction relative to the first surface, a first passivation layer positioned on the first surface, a second passivation layer positioned on the second surface, a first sol-gel layer positioned on the first passivation layer, a second sol-gel layer positioned on the second passivation layer, and a finish coating including protective resin positioned on the first sol-gel layer. The first passivation layer and the second passivation layer can independently include a molybdate, a vanadate, a phosphate, a chromate, a stannate, or a manganese salt. The first sol-gel layer and the second sol-gel layer can independently include a silicate, a silane, a siloxane, or a metal C1-C5 alkoxide. In one example, the first sol-gel layer and the second sol-gel layer independently include tetraethylorthosilicate, tetramethylorthosilicate, tetraisopropoxysilane, aluminum isopropoxide, titanium isopropoxide, aluminum tert-butoxide, glycidoxypropyltriethoxysilane, 3-aminopropyltriethoxysilane, methacryloxypropyltrimethoxysilane, vinyltrimethylsiloxane, diphenyldimethoxysilane, zirconium isopropoxide, or a combination thereof. The finish coating can include one or multiple finishing layers, and the finish coating can have a total thickness from about 10 μm to about 70 μm. For example, the finish coating can include multiple finishing layers, including a visible protection layer with particulates suspended in a resin positioned on the sol-gel coating layer, and a clear protection layer including the same resin or a different resin positioned on the visible protection layer. The particulates can include carbon black, titanium dioxide, clay, mica, talc, barium sulfate, calcium carbonate, synthetic pigment, metallic powder, aluminum oxide (alumina), zirconia, aluminum silicate, zirconium silicate, alumina-zirconia, chromia, graphene, graphite, or a combination thereof. The passivation layer can have a thickness from about 0.3 μm to about 5 μm. The sol-gel layer can have a thickness from about 2 μm to about 15 μm.

In another example, a method of protecting a magnesium alloy from corrosion can include applying a passivation layer at a thickness from about 0.3 μm to about 5 μm to a magnesium alloy substrate, wherein the passivation layer includes a molybdate, a vanadate, a phosphate, a chromate, a stannate, or a manganese salt. The method can further include applying a sol-gel layer at a thickness of about 2 μm to about 15 μm to a passivation layer, wherein the sol-gel layer includes a silicate, a silane, a siloxane, or a metal C1-C5 alkoxide. In one example, the method can further include applying a finish coating to the sol-gel layer, wherein the finish coating includes one or multiple layers applied at a total thickness of about 10 μm to about 70 μm.

It is noted that when discussing either the magnesium alloy layered composites, the electronic device, or the method of protecting magnesium alloy from corrosion herein, such discussions can be considered applicable to one another whether or not they are explicitly discussed in the context of that example. Thus, for example, when discussing the passivation layer in the context of one of the magnesium alloy layered composites, such disclosure is also relevant to and directly supported in the context of the electronic device, the method, or both, and vice versa. It is also understood that terms used herein will take on their ordinary meaning in the relevant technical field unless specified otherwise. In some instances, there are terms defined more specifically throughout or included at the end of the present disclosure, and thus, these terms are supplemented as having a meaning described herein.

In further detail, it is noted that the spatial relationship between layers is often described herein as positioned “on” or applied “on” another layer and does not infer that this layer is positioned directly on the layer to which it refers, but could have intervening layers therebetween. That being stated, a layer described as being positioned on another layer can be positioned directly on that other layer, and thus such a description finds support herein for being positioned directly on the referenced layer.

### Magnesium Alloy Substrate

The magnesium alloy substrates described herein can be of any configuration, thickness, finish, etc., suitable for application of the subsequent layers described herein. In one example, however, the magnesium alloy substrate can be in the shape of a housing, panel, support, chassis, or other support substructure suitable for use with an electronic device. In one example, the magnesium alloy substrate can be rigid with a thickness suitable for such an electronic device housing, panel, support, chassis, etc. For example, when in the form of a housing, the magnesium alloy substrate can be appropriately shaped for use as a desktop tower housing, a laptop housing, a keyboard housing, a monitor housing, a tablet housing, a smartphone or cellular phone housing, etc., and can be configured or shaped by molding and/or machining, for example. In particular, the magnesium alloy substrate can be an alloy with any of a number of other metals, semi-metals, or other compound or elements. Metals alloyed with magnesium can include aluminum, lithium, titanium, zinc, chromium, strontium, antimony, etc. Semi-metals can include silica, alumina, etc. Other materials can include carbon, oxygen, rare earth elements, etc. One specific example of a magnesium alloy that can be used is referred to as AZ31 B Magnesium alloy, which includes about 96 atomic percent (wt%) magnesium, about 3 at % aluminum, and about 1 wt % zinc.

When used as an electronics housing or panel, the thickness of the magnesium alloy substrate can depend on the alloy material chosen, the density of the material (for purposes of controlling weight, for example), the hardness of the material, the malleability of the material, etc. In some examples, however, the thickness of the magnesium alloy substrate when used as a housing or panel can be from about 2 mm to about 2 cm, or from about 3 mm to about 1.5 cm, or from about 4 mm to about 1 cm.

### Passivation Layer

A magnesium alloy substrate may be treated with a passivation layer to protect magnesium alloy from corrosion. The passivation layer can include, for example, various passivation compounds, such a chromate, a phosphate, a molybdate, a vanadate, a stannate, a manganese salt, or a combination thereof. In some examples, a passivation treatment process to generate a passivation layer can include dissolving or dispersing a passivating compound, such as one of the passivating compounds, in a solution and immersing the substrate in the solution to form a layer of the passivating compound on the substrate. The solution or dispersion of the passivating compound can include the passivating compound, for example, at from about 1 wt % to about 10 wt %, from about 1.5 wt % to about 7.5 wt %, or from about 2 wt % to about 5 wt %. Examples of passivation treatment processes that generate conversion coatings by this or other similar processes can include processes that generate a chromate conversion coating, a phosphate conversion coating, a molybdate conversion coating, a vanadate conversion coating, a stannate conversion coating, manganese salt conversion coating, etc. In some examples, the substrate can be passivated on one side, or on both sides. In some examples, the passivation layer can have a thickness from about 0.3 μm to about 5 μm, from about 0.4 μm to about 4 μm, or from about 0.5 μm to about 3 μm. The passivation layer can, in some instances, improve the mechanical, wear, thermal, dielectric, and corrosion properties of the substrate.

Sol-gel Layer

In addition to the passivation layer applied as described above, a sol-gel layer can be applied thereon so that the magnesium alloy layered composite includes the sol-gel layer on one side or both sides thereof. “Sol-gel layer(s)” refers to the formation of an inorganic compound in the form of a network of inorganic elements that may be attached or adsorbed on a surface of a previously applied passivation layer. The sol-gel layer can provide resistance to corrosion of the magnesium alloy substrate, and/or can provide adhesion properties to a subsequently applied finishing coating.

The sol-gel layer can be, for example, an interconnected network of multiple “precursor compounds” that form a web of interconnected (now modified) precursor compounds as a result of hydrolysis and condensation reaction(s). More specifically, a sol-gel reaction can be controlled or otherwise occur to form a sol-gel layer on a passivation layer based on the reaction conditions, reactants, and dynamics, e.g., rate, of hydrolysis of the precursor compound and/or condensation of an alcohol in a reaction mixture thereof. Still more specifically, a sol-gel reaction can result in various types of network structures obtained by controlling pH, temperature, properties and concentrations of a catalyst, concentrations of the precursor compound, concentrations of other reactants that may be added, etc. Regardless of the precursor compound(s) used, the reaction conditions, dynamics, etc., any network or web of interconnected material that may be formed is within the scope of the present disclosure. Thus, the sol-gel layer may be prepared from various types of precursor compounds of a colloidal solution, e.g., the “sol,” that can then react to generate the interconnected network, e.g., the “gel,” sol-gel layer. Typical precursor compounds can include metal C1-C5 alkoxides, e.g., methoxy, ethoxy, isopropoxy, n-propoxy, n-butoxy, iso-butoxy, tert-butoxy; silicon, e.g., silicates, silanes, etc.; titanium; aluminum; or the like. Example sol-gel layers can include, for example, tetraethylorthosilicate (TEOS), tetramethylorthosilicate, tetraisopropoxysilane, aluminum isopropoxide, titanium isopropoxide, aluminum tert-butoxide, glycidoxypropyltriethoxysilane (GPTMS), 3-aminopropyltriethoxysilane (APTES), methacryloxypropyltrimethoxysilane, vinyltrimethylsiloxane (VTMS), diphenyldimethoxysilane (DPhDMS), zirconium isopropoxide (TPZ), or a combination thereof.

The sol-gel layer can be applied at a thickness from about 2 μm to about 15 μm, from about 3 μm to about 12 μm, or from about 4 μm to about 10 μm to one side or both sides as part of the magnesium alloy layered composite.

### Finish Coating

In some examples, the magnesium alloy layered composite can include a finish coating, which can be a coating of a single finishing layer or multiple layers. The finish coating can include a protective resin, for example, and can act as a clear protective coating, a visible protective coating, e.g., color, black, white, gray, sheen, etc., or can be layered with both types of coatings. Thus, the term “finish coating” refers to all finishing layers that may be present, whether it be a single finish layer or multiple finishing layers. For example, one type of finishing layer that can be included is a clear protection layer, and another type of finishing layer that can be included is a visible protection layer. Specific examples of such layers include various types of paint, whether transparent (clear protection layer) or colored, black, white, metallic, etc. (visible protection layer), or both. In some examples, one or both finishing layer(s) can be applied on a previously applied sol-gel layer (to one side or both sides) to form a finish coating. In one example, the visual protection and the clear protection layer can be sequentially applied on the sol-gel layer, e.g., clear protection layer may be the outermost layer. Though more specific thickness for the various types of finish layers is proved below, in some examples, the finish coating (which can be the aggregate of one or multiple finishing layers) can have a total thickness from about 10 μm to about 70 μm, from about 15 μm to about 60 μm, or from about 20 μm to about 50 μm.

The clear protection layer can be of a polymeric layer that protects (as part of the composite) the outer surface of the magnesium alloy layered composite, but which allows the look of the layer therebeneath to be seen by the user. The polymer layer can thus include, for example, any polymer resin or lacquer that is clear, dry to the touch after applied and dried, etc. Polymers such as epoxy-acrylate, urethane-acrylate, polyether-acrylate, polyester-acrylate, epoxy, polyurethane, or a combination thereof, zo can be used. The polymer can have a weight average molecular weight from about 1,000 Mw to about 10,000 Mw, from about 1,000 Mw to about 6,000 Mw, from about 1,500 Mw to about 5,000 Mw, or from about 2,000 Mw to about 3,500 Mw. In some examples, the clear protection can be prepared from a clear protective coating composition that is applied to a previously applied layer(s). The polymer binder can be included in the clear protection layer in an amount of about 70 wt % to about 100 wt %, from about 80 wt % to about 100 wt %, or from about 90 wt % to about 100 wt % (by dry weight in the clear protection layer). Heat can be applied, for example, at from about 50° C. to about 90° C. for about 5 minutes to about 45 minutes or from about 10 minutes to about 45 minutes, or from about 60° C. to about 80° C. for about 15 minutes to about 40 minutes, for example. In one specific example, drying can be by baking at about 50° C. to about 60° C. for about 5 minutes to about 10 minutes. In other examples, drying or baking can include or be followed by UV curing, such as at about 500 mJ/cm² to about 1,500 mJ/cm², or from about 800 mJ/cm² to about 1,200 mJ/cm². In examples with UV curing, the clear protection layer can include a photoactive agent that is sensitive to UV energy application, such as a methyl radical, an allylic radical, or a hydroxyl radical. If included, the clear protection layer can be applied at a thickness from about 5 μm to about 35 μm, from about 10 μm to about 30 μm, or from about 15 μm to about 25 μm.

The visible protection layer may be formulated similar to the clear protection layer, but can include other particulate components added to the polymer to provide visual properties such as a colored appearance, black appearance, gray appearance, white appearance, reflective appearance, matte appearance, ceramic appearance, etc. This layer, if present, can be referred to as a “visible protection layer” because it can provide protection as well as impart a visual property or properties to the composite. Example particulates that can be present include carbon black, titanium dioxide, clay, mica, talc, barium sulfate, calcium carbonate, synthetic pigment, metallic powder, aluminum oxide (alumina), zirconia, aluminum silicate, zirconium silicate, alumina-zirconia, chromia, graphene, graphite, or a combination thereof. These various particulates can have a particle size from about 0.1 μm to about 10 μm, from about 0.3 μm to about 7 μm, or from about 0.5 μm to about 5 μm, for example, which is based on the length of the ceramic particles along the longest dimension. In one example, the particulates can have an aspect ratio from about 1:1 to about 5:1 (based on longest dimension to shortest dimension), and can have a variety of morphologies, including spherical, rounded, angular, spongy, flakey, cylindrical, acicular, cubic, etc. The particulates can be included in the visible protection layer at from about 0.5 wt % to about 20 wt %, from about 1 wt % to about 18 wt %, from about 2 wt % to about 15 wt %, from about 3 wt % to about 15 wt %, from about 4 wt % to about 12 wt %, or from about 5 wt % to about 10 wt %, by dry weight, for example.

Furthermore, like the clear protection layer, the visible protection layer can also include a polymer binder and can be prepared from a visible protection coating composition to form the visible protection layer. The polymer binder can be included in the visual protection layer in an amount of about 70 wt % to about 99.5 wt % (by dry weight in the visible protection layer). The polymer binder can be, for example, any polymer resin suitable for binding the various particles together, such as epoxy-acrylate, urethane-acrylate, polyether-acrylate, polyester-acrylate, epoxy, polyurethane, or a combination thereof. The polymer can have a weight average molecular weight from about 1,000 Mw to about 12,000 Mw, from about 1,000 Mw to about 8,000 Mw, from about 2,000 Mw to about 6,000 Mw, or from about 2,500 Mw to about 5,000 Mw. Heat can be applied, for example, at from about 50° C. to about 90° C. for about 5 minutes to about 45 minutes or from about 10 minutes to about 45 minutes, or from about 60° C. to about 80° C. for about 15 minutes to about 40 minutes. In one specific example, drying can be by baking at about 50° C. to about 60° C. for about 5 minutes to about 10 minutes. In other examples, drying or baking can include or be followed by UV curing, such as at about 500 mJ/cm² to about 1,500 mJ/cm², or from about 800 mJ/cm² to about 1,200 mJ/cm². In examples with UV curing, the visible protection layer can include a photoactive agent that is sensitive to UV energy application, such as a methyl radical, an allylic radical, or a hydroxyl radical. If included, the visible protection layer can be applied at an average thickness from about 5 μm to about 35 μm, from about 10 μm to about 30 μm, or from about 15 μm to about 25 μm.

### Coated Substrates

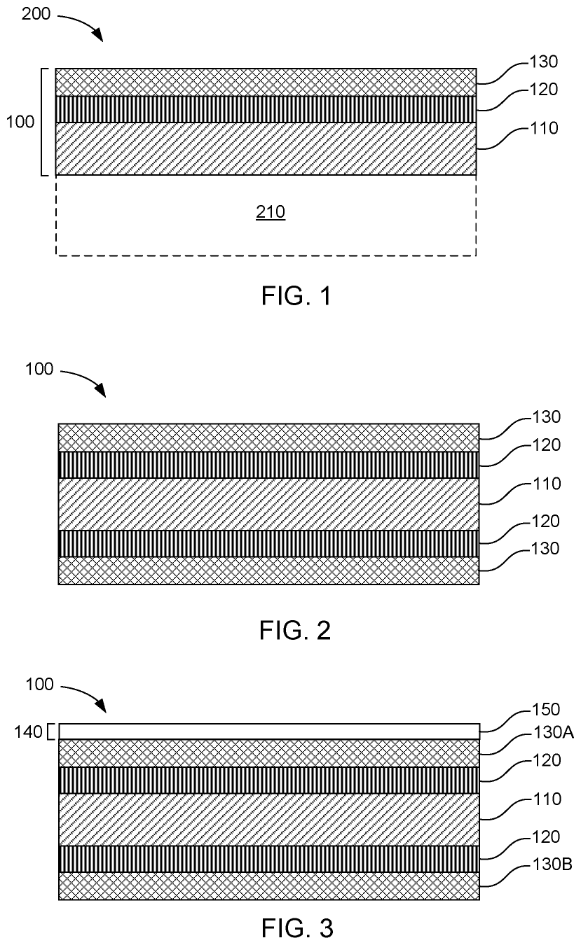

Example magnesium alloy composites prepared in accordance with the zo present disclosure are shown in FIGS. 1-3, which include a magnesium alloy substrate, a passivation layer, and a sol-gel layer. Some of the examples shown in the FIGS. further include various arrangements of additional finishing layers, e.g., colored resin coating with dispersed particles, clear protection layers, etc. The layers applied to one another can be bound together as a composited layered structure.

More specifically, with respect to FIG. 1, a magnesium alloy layered composite 100 for an electronic device 200 can include a magnesium alloy substrate 110, a passivation layer 120 positioned on the magnesium alloy substrate, and a sol-gel layer 130 positioned on the passivation layer. The passivation layer can include a molybdate, a vanadate, a phosphate, a chromate, a stannate, or a manganese salt, for example. The sol-gel layer can include a silicate, a silane, a siloxane, or a metal C1-C5 alkoxide, for example. The electronic device can include electronic component 210 supported or protected or positioned adjacent to the magnesium alloy layered composite. As a note, in FIGS. 2-5 hereinafter, the electronic device is not shown, but it is understood that the magnesium alloy layered composites shown in FIGS. 2-5 likewise can be associated with or configured as part of an electronic device. The thicknesses can be as described previously.

In FIG. 2, an alternative magnesium alloy layered composite 100 is shown, which includes a magnesium alloy substrate 110 and two passivation layers 120, one positioned on a first side of the magnesium alloy substrate and one positioned on the other side of the magnesium alloy substrate. Furthermore, two a sol-gel layers 130 are also included, which are positioned on the two passivation layers, respectively. The passivation layers can independently include a molybdate, a vanadate, a phosphate, a chromate, a stannate, or a manganese salt, for example. The sol-gel layer can independently include a silicate, a silane, a siloxane, or a metal C1-C5 alkoxide, for example. The thicknesses can be as described previously. In some examples, both passivation layers are of the same material and/or thickness. In other examples, both sol-gel layers are of the same material and/or thickness.

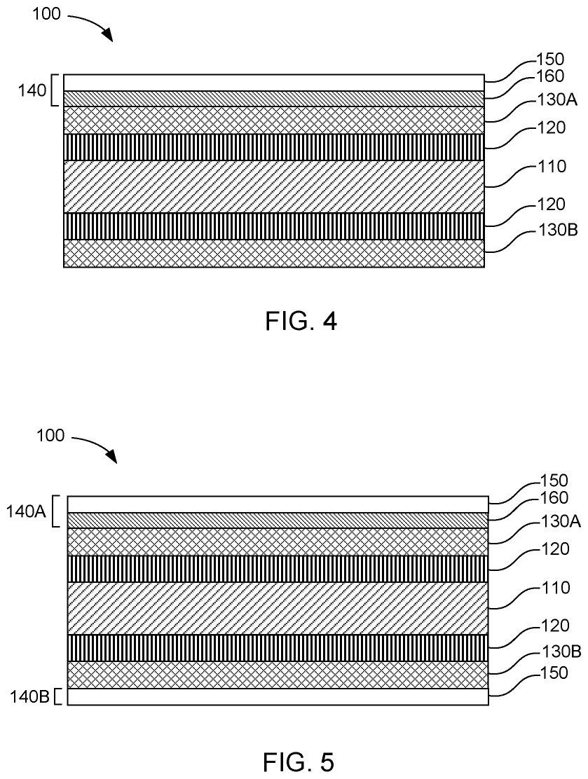

In FIGS. 3 and 4, the same structure as shown in FIG. 2 is included in these FIGS., except that one of the sol-gel layers 130A is coated with a finish coating 140. The finish coating in the example shown in FIG. 3 includes a single clear protection zo layer 150. The finish coating in FIG. 4 includes both a visible protection layer 160 and a clear protection layer 150 positioned thereon. The other structures and layers are as described previously, including the magnesium alloy substrate 110, the passivation layers 120, and the sol-gel layers 130A, 130B. The thicknesses can be as described previously.

In FIG. 5, the same structure as shown in FIG. 2 is again present, except that one of the sol-gel layers 130A is coated with a finish coating 140A that includes both a visible protection layer 160 and a clear protection layer 150. The other sol-gel layer 130B is alternatively coated with a finish coating 140B with a single clear protection layer 150. The other structures and layers are as described previously, including the magnesium alloy substrate 110, the passivation layers 120, and the sol-gel layers 130A,130B. The thicknesses can be as described previously. It is noted that both sides of the magnesium alloy layered composite 100 can include the same finish coating (not shown) or different finish coatings, as shown by example.

### Methods of Coating Substrates

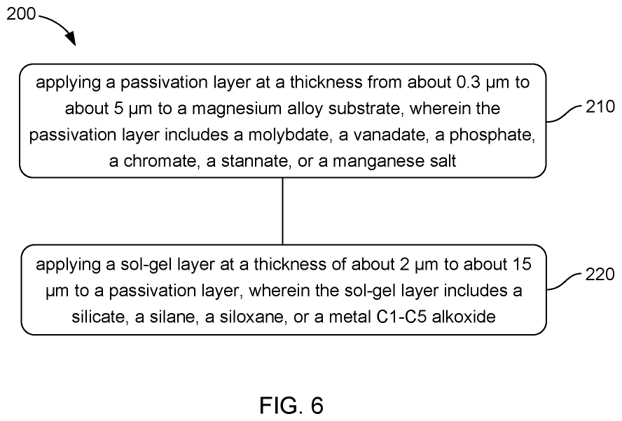

Turning now to FIG. 6, a method 200 of protecting a magnesium alloy from corrosion can include applying 210 a passivation layer at a thickness from about 0.3 μm to about 5 μm to a magnesium alloy substrate, wherein the passivation layer includes a molybdate, a vanadate, a phosphate, a chromate, a stannate, or a manganese salt. The method can also include applying a sol-gel layer at a thickness of about 2 μm to about 15 μm to a passivation layer, wherein the sol-gel layer includes a silicate, a silane, a siloxane, or a metal C1-C5 alkoxide. In one example, the method can further include applying a finish coating to the sol-gel layer, wherein the finish coating includes one or multiple finishing layers applied at a total thickness of about 10 μm to about 70 μm. In further detail, the substrates, layers, coatings, etc., described herein as it relates to the magnesium alloy layered composites and/or electronic devices are applicable to the methods herein and thus the details are incorporated into the description of the method examples as described.

### Definitions

It is noted that, as used in this specification and the appended claims, the singular forms “a,” “an,” and “the” include plural referents unless the content clearly dictates otherwise.

The term “about” as used herein, when referring to a numerical value or range, allows for a degree of variability in the value or range, for example, within 5 % or other reasonable added range breadth of a stated value or of a stated limit of a range.

The term “about” when modifying a numerical range is also understood to include the exact numerical value indicated, e.g., the range of about 0.1 wt % to about 2 wt % includes 0.1 wt % to 2 wt %, as an explicitly supported sub-range.

As used herein, the term “composite” refers to the act of combining individual elements, e.g., substrate, layers, coatings, etc., into a single unified structure with structures, layers, coatings, etc., being physically and/or chemically bound together along one or more interface.

The term “electronic device” refers to assemblies of structural support(s) and/or housing(s) assembled with electronic component(s). The electronic components may have electrical, mechanical, and/or electromechanical function, for example. The structural support(s) and/or housing(s) may further have aesthetic appeal in addition to the support and/or structure that they may provide. Typically, the metal alloy layered composites of the present disclosure can be used for housing(s) and/or structural support(s), and may have an aesthetic appearance to some users. Thus, the magnesium alloy layered composites of the present disclosure can be used to house individual electronic components or electronic component assemblies, such as on an interior of an electronic device housing, or as a sub-housing of a larger electronic device, or can act as an outermost housing of an electronic device, for example.

The term “composition” herein typically refers to the formulation that is used to form a “layer” or a “coating” after application and in some instances, drying and/or photo curing. Thus, the composition may include solvent or other carrier that may be driven off to leave behind a dry layer, or may include components where reaction can be initiated by UV curable energy, for example.

Numerical values are typically provided and refer to the average of the numerical value given. For example, a thickness range for a layer of from about 5 μm to about 25 μm indicates the range as it relates to the average thickness of the layer.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, as well as to include all the individual numerical values or sub-ranges encompassed within that range as if each numerical value and sub-range is explicitly recited. For example, a weight percentage range of a layer (by dry weight) of about 0.1 wt % to about 2 wt % should be interpreted to include the explicitly recited limits of 0.1 wt % and 2 wt %, as well as to include individual weights therebetween, such as about 0.5 wt %, 1 wt %, 1.5 wt %, and sub-ranges such as about 0.2 wt % to about 1.5 wt %, 0.5 wt % to about 1 wt %, etc.

### EXAMPLES

The following illustrates an example of the present disclosure. However, it is to be understood that the following is illustrative of the application of the principles of the present disclosure. Numerous modifications and alternative compositions, methods, and systems may be devised without departing from the spirit and scope of the present disclosure. The appended claims are intended to cover such modifications and arrangements.

### Example 1—Passivation Layer Application

A passivation layer is applied to both sides of a magnesium alloy substrate (plate-like configuration having a thickness of about 7 mm) with 96 at % magnesium, 3 at % aluminum, and 1 at % zinc (AZ31) by dipping the substrate in solution of a passivating compound. The solution included water, 3 wt % phosphate compound as the passivating compound, and 2 wt % citric acid. The processing temperature is about 30° C. to about 45° C. for about 30 seconds to about 3 minutes. The passivating layer resulting from this conversion coating process on both sides of the substrate is about 0.8 μm in thickness.

### Example 2—Sol-gel Layer Application

An emulsion is prepared that includes a continuous aqueous phase, a discontinuous organosilane phase of a dodecyltimethoxysilane precursor compound, and sodium caseinate surfactant. Based on the emulsion as a whole, the aqueous phase is water and is included in the emulsion at about 89 wt %, the dodecyltimethoxysilane precursor is included in the emulsion at about 10 wt %, and the surfactant is included in the emulsion at about 1 wt %. Once prepared, the emulsion is agitated and centrifuged at about 400 RPM prior and heated to about 50° C. The magnesium alloy substrate with the passivation layers (on both sides) is then dipped in the emulsion for about 60 seconds and then removed and dipped in the emulsion prepared in 6) above for 60 seconds and then removed, leaving a sol-gel layer on both side having a thickness of about 3 μm.

### Example 3—Finish Coating Application

A finish coating including a visible protection layer, e.g., colored paint layer, and a clear protection layer is applied to one side of the magnesium alloy layered composite prepared stepwise in Examples 1 and 2. The visible protection layer is prepared by dispersing about 1.2 wt % carbon black, 27 wt % organic solvent, and about 71.8 wt % polyurethane, and then applying to the sol-gel layer at a thickness of about 8 μm by a dipping process, followed by baking for about 30 minutes at about 80° C. Alternatively, the visible protection layer can be made to be white using the same concentration of titanium dioxide instead of carbon black. The clear protection layer is applied in the same manner, with the exception that the dispersed particles of carbon black are not included in the composition.

### Example 4—Corrosion Resistance

A magnesium metal alloy substrate (AZ31B) without passivation layers, sol-gel layers, or finish coating (referred to as “substrate”) was compared to the magnesium alloy layered composite prepared in accordance with Examples 1-3 (referred to as “layered composite”) for corrosion resistance. The corrosion testing carried out was a salt fog test, where an aerosolized salt fog of salt solution concentration 5±1 wt % and temperature 35±2° C. (95±4° F.) was generated, and the substrate and the layered composite were individually subjected to the aerosolized salt fog until any suspected areas of corrosion or failure of the surface occurred. The substrate failed after 8 hours of exposure to the salt fog environment, whereas the layered composite was still resisting failure at 96 hours.

What has been described and illustrated herein include examples of the disclosure along with some of its variations. The terms, descriptions, examples, and figures used herein are set forth by way of illustration and are not meant as limitations. Many variations are possible within the scope of the disclosure, which is intended to be defined by the following claims—and their equivalents—in which all terms are meant in their broadest reasonable sense unless otherwise indicated.

What is claimed is:

1. A magnesium alloy layered composite for an electronic device, the magnesium alloy layered composite comprising:
a magnesium alloy substrate;
a passivation layer positioned on the magnesium alloy substrate, wherein the passivation layer includes a molybdate, a vanadate, a phosphate, a chromate, a stannate, or a manganese salt; and
a sol-gel layer positioned on the passivation layer, wherein the sol-gel layer includes a silicate, a silane, a siloxane, or a metal C1-C5 alkoxide.

2. The magnesium alloy layered composite of claim 1, wherein the sol-gel layer comprises tetraethylorthosilicate, tetramethylorthosilicate, tetraisopropoxysilane, aluminum isopropoxide, titanium isopropoxide, aluminum tert-butoxide, glycidoxypropyltriethoxysilane, 3-aminopropyltriethoxysilane, methacryloxypropyltrimethoxysilane, vinyltrimethylsiloxane, diphenyldimethoxysilane, zirconium isopropoxide, or a combination thereof.

3. The magnesium alloy layered composite of claim 1, further comprising a finish coating including a protective resin positioned on the sol-gel layer.

4. The magnesium alloy layered composite of claim 3, wherein the finish coating includes one or multiple finishing layers having a total thickness from about 10 μm to about 70 μm.

5. The magnesium alloy layered composite of claim 3, wherein the finish coating comprises multiple finishing layers, including a visible protection layer with particulates suspended in a resin positioned on the sol-gel coating layer, and a clear protection layer including the same resin or a different resin positioned on the visible protection layer.

6. The magnesium alloy layered composite of claim 5, wherein the particulates include carbon black, titanium dioxide, clay, mica, talc, barium sulfate, calcium carbonate, synthetic pigment, metallic powder, aluminum oxide (alumina), zirconia, aluminum silicate, zirconium silicate, alumina-zirconia, chromia, graphene, graphite, or a combination thereof.

7. The magnesium alloy layered composite of claim 1, wherein the passivation layer is from about 0.3 μm to about 5 μm in thickness, and the sol-gel layer is from about 2 μm to about 15 μm in thickness.

8. An electronic device comprising:
a magnesium alloy layered composite comprising:
a magnesium alloy substrate with a first surface and a second surface facing an opposing direction relative to the first surface;
a first passivation layer positioned on the first surface, wherein the first passivation layer includes a molybdate, a vanadate, a phosphate, a chromate, a stannate, or a manganese salt;
a second passivation layer positioned on the second surface, wherein the second passivation layer includes a molybdate, a vanadate, a phosphate, a chromate, a stannate, or a manganese salt;
a first sol-gel layer positioned on the first passivation layer, wherein the first sol-gel layer includes a silicate, a silane, a siloxane, or a metal C1-C5 alkoxide;
a second sol-gel layer positioned on the second passivation layer, wherein the first sol-gel layer includes a silicate, a silane, a siloxane, or a metal C1-C5 alkoxide; and
a finish coating including protective resin positioned on the first sol-gel layer.

9. The magnesium alloy layered composite of claim 8, wherein the first sol-gel layer and the second sol-gel layer independently include tetraethylorthosilicate, tetramethylorthosilicate, tetraisopropoxysilane, aluminum isopropoxide, titanium isopropoxide, aluminum tert-butoxide, glycidoxypropyltriethoxysilane, 3-aminopropyltriethoxysilane, methacryloxypropyltrimethoxysilane, vinyltrimethylsiloxane, diphenyldimethoxysilane, zirconium isopropoxide, or a combination thereof.

10. The magnesium alloy layered composite of claim 8, wherein the finish coating includes one or multiple finishing layers having a total thickness from about 10 μm to about 70 μm.

11. The magnesium alloy layered composite of claim 8, wherein the finish coating comprises multiple finishing layers, including a visible protection layer with particulates suspended in a resin positioned on the sol-gel coating layer, and a clear protection layer including the same resin or a different resin positioned on the visible protection layer.

12. The magnesium alloy layered composite of claim 11, wherein the particulates include carbon black, titanium dioxide, clay, mica, talc, barium sulfate, calcium carbonate, synthetic pigment, metallic powder, aluminum oxide (alumina), zirconia, aluminum silicate, zirconium silicate, alumina-zirconia, chromia, graphene, graphite, or a combination thereof.

13. The magnesium alloy layered composite of claim 8, wherein the first and second passivation layers are individually from about 0.3 μm to about 5 μm in thickness, and the first and second sol-gel layers are individually from about 2 μm to about 15 μm in thickness.

14. A method of protecting a magnesium alloy from corrosion comprising:
applying a passivation layer at a thickness from about 0.3 μm to about 5 μm to a magnesium alloy substrate, wherein the passivation layer includes a molybdate, a vanadate, a phosphate, a chromate, a stannate, or a manganese salt; and
applying a sol-gel layer at a thickness of about 2 μm to about 15 μm to a passivation layer, wherein the sol-gel layer includes a silicate, a silane, a siloxane, or a metal C1-C5 alkoxide.

15. The method of claim 14, further comprising applying a finish coating to the sol-gel layer, wherein the finish coating includes one or multiple finishing layers applied at a total thickness of about 10 μm to about 70 μm.
